(19) United States
(12) Patent Application Publication
(10) Pub. No.: US 2025/0388103 A1
(43) Pub. Date: Dec. 25, 2025

(54) ELECTRIC VEHICLE CHARGING ADAPTOR WITH FORCED-AIR COOLING

(71) Applicants: Jevne B. Cunningham, Robbinsdale, MN (US); Anthony Butay, Robbinsdale, MN (US)

(72) Inventors: Jevne B. Cunningham, Robbinsdale, MN (US); Anthony Butay, Robbinsdale, MN (US)

(21) Appl. No.: 19/248,123

(22) Filed: Jun. 24, 2025

Related U.S. Application Data
(60) Provisional application No. 63/664,083, filed on Jun. 25, 2024.

(51) Int. Cl. B60L 53/302; B60L 53/16; H05K 7/20

(52) U.S. Cl. CPC B60L 53/302; B60L 53/16; H05K 7/20145; H05K 7/20154; H05K 7/20172; H05K 7/20409

(57) ABSTRACT

The present disclosure relates to heat dissipation during electric vehicle charging. Examples of the disclosure include a charging adaptor used as an intermediate coupling between a charging modality and an electric vehicle. Charging adaptors of the present disclosure can also include integrated cooling to dissipate heat generated during charging. In some examples, a charging adaptor may include a housing defining one or more vents, at least one fan unit positioned within the housing proximate to the one or more vents, and a heat sink positioned within the housing proximate to the at least one fan unit. The heat sink can absorb heat generated during electric vehicle charging. The at least one fan unit can draw outside air into the housing through the one or more vents and can direct the outside air along the heat sink to cool the charging adaptor.

### CROSS-REFERENCE TO RELATED APPLICATION

The present application claims the priority benefit of U.S. Provisional Application No. 63/664,083, filed Jun. 25, 2024 and titled “EV CHARGING MODE ADAPTOR COUPLER WITH FORCED-AIR COOLING,” which is hereby incorporated by reference in its entirety.

### TECHNICAL FIELD

The present disclosure generally relates to electric vehicle charging. More particularly, the present disclosure relates to heat dissipation during electric vehicle charging.

### BACKGROUND

Heat is generated during electric vehicle charging due to the passage of high electrical currents between a charger and the electric vehicle. This phenomenon, commonly referred to as Joule heating, occurs when the passage of electric current through a conductor produces heat. This heat is particularly pronounced at the interfaces where a charging station charging modality connects to a vehicle inlet, as well as within any intermediary adaptors used to couple the charging modality to the inlet. Intermediary adaptors are generally used to couple charging modalities and electric vehicles that are otherwise incompatible. For example, an adaptor may be used to couple an SAE J1772 electric vehicle to a North American Charging System (NACS) charging modality or to a CHAdeMO charging modality commonly used in Japan.

Excessive heat buildup during charging can present safety hazards including the risk of melting components, damaging sensitive electronic components, and in extreme cases, causing fires. Overheating can also degrade the performance and lifespan of charging equipment, vehicle charging ports, and any intermediary adaptors. Overheating may also extend charging times, which can increase the cost for customers to charge their vehicles.

Various cooling strategies have been implemented with electric vehicle charging systems in an effort to mitigate these risks. Conventional passive approaches include the use of materials with high thermal conductivity, large contact surfaces, and heat sinks positioned within charging modalities or vehicles to enhance heat dissipation away from critical components. Additionally, some conventional charging systems incorporate liquid cooling loops within charging modalities or vehicles. The liquid cooling loops circulate coolant that absorbs and transfers heat away from high thermal load areas. Users are also sometimes instructed to interrupt charging sessions and allow overheated components to cool before resuming charging.

Despite these measures, effectively managing heat generation during electric vehicle charging remains challenging, particularly as charging speeds and system interoperability demands continue to rise. Challenges associated with heat mitigation can be more pronounced when an intermediary adaptor couples certain incompatible charging station charging modalities and electric vehicles. Heat generated by the passage of electric current can be transferred to the adaptor where it can accumulate during charging. Without adequate cooling, heat accumulated in the adaptor can lead to elevated temperatures that may compromise the structural integrity of the adaptor, or may further exacerbate the risk of overheating at the electrical connection interfaces. This may also negatively impact charging speeds from the charging system to the electric vehicle.

### SUMMARY

The present disclosure addresses issues with conventional cooling systems by providing charging adaptors having integrated cooling systems. Charging adaptors of the present disclosure provide at least one fan unit configured to direct air along a heat sink to cool electrical contacts during electric vehicle charging. As a result, electrical contact points at the interface where the charging modality is coupled to the adaptor, and the interface where the adaptor couples to the vehicle, can be cooled. This prevents damage to the charging components due to overheating. Providing a charging adaptor with an integrated cooling system also enables use with a variety of charging modalities and electric vehicles designed according to different charging standards, some of which may otherwise be incompatible. Accordingly, the present disclosure provides several improvements to cooling and heat dissipation during electric vehicle charging which enhance safety, extend component lifespan, and provide reliable operation across a wide range of charging conditions and standards.

Non-limiting examples of the present disclosure provide charging adaptors for electric vehicles. The charging adaptors can include a housing defining one or more vents, at least one fan unit positioned within the housing proximate to the one or more vents, and a heat sink positioned within the housing proximate to the at least one fan unit. The heat sink can be configured to absorb heat generated during electric vehicle charging. The at least one fan unit can be configured to draw outside air into the housing through the one or more vents and can be further configured to direct the outside air along the heat sink.

In some examples, the at least one fan unit can include a first fan unit and a second fan unit. In some examples, the at least one fan unit can include a fan duct and a forced-air fan. In some examples the at least one fan unit can be further configured to exhaust the outside air out of the housing through the one or more vents after the outside air is directed along the heat sink. In some examples, the heat sink can include a plurality of fins extending outward from a mount plate. In some examples, the at least one fan unit can be powered by an electrical power source positioned within the housing. In some examples, the at least one fan unit can be powered by a battery. In some examples, the charging adaptor can further include one or more electrical contacts. Heat generated by the one or more electrical contacts during charging can be transferred to a heat-conducting dielectric positioned within the housing, and then transferred from the heat-conducting dielectric to the heat sink. In some examples, the one or more electrical contacts can include a charging plug having one or more conductors for transmitting electrical current.

Non-limiting examples of the present disclosure provide charging adaptors for electric vehicles. The charging adaptors can include a housing defining one or more vents, one or more electrical contacts coupled to the housing, a dielectric positioned proximate to the one or more electrical contacts, a first fan unit positioned within the housing proximate to the one or more vents, a second fan unit positioned within the housing proximate to the one or more vents, and a heat sink positioned within the housing proximate to each of the dielectric, the first fan unit, and the second fan unit. Heat generated by the one or more electrical contacts during electric vehicle charging can be transferred first to the dielectric and then to the heat sink. The first fan unit can draw outside air into the housing through the one or more vents and can direct the outside air along the heat sink. The second fan unit can exhaust the outside air out of the housing through the one or more vents after the outside air is directed along the heat sink.

In some examples, the one or more vents can include at least one vent defined on a first side of the housing and at least one vent defined on a second side of the housing. The first fan unit can be positioned proximate to the at least one vent on the first side and the second fan unit can be positioned proximate to the at least one vent on the second side. In some examples, the one or more vents can include a first vent and a second vent defined in a bottom surface of the housing. The first and second vents can be defined proximate to an electrical contact of the one or more electrical contacts, for example a charging socket of the charging adaptor. In some examples, the heat sink can include a plurality of fins extending outward from a mount plate toward the first fan unit and the second fan unit. In some examples, the first fan unit and the second fan unit can be powered by at least one of an electrical source positioned within the housing and a battery. In some examples, the first fan unit and the second fan unit can each include a fan duct and a forced-air fan. In some examples, the one or more electrical contacts can include a charging plug having a plurality of conductors. The plurality of conductors can generate heat during electric vehicle charging that is transferred to the dielectric.

Non-limiting examples of the present disclosure provide cooling systems for electric vehicle charging adaptors. The cooling systems can include a first fan unit configured to draw outside air into the charging adaptor, a second fan unit configured to exhaust air out of the charging adaptor, and a heat sink having a plurality of fins extending from a mount plate. The heat sink can be configured to receive heat generated during electric vehicle charging. The first fan unit can draw outside air into the charging adaptor and can direct the outside air along the heat sink. The second fan unit can exhaust the outside air out of the charging adaptor after the outside air is directed along the heat sink.

In some examples, the first fan unit and the second fan unit can be horizontally aligned or angled with respect to the mount plate, such that air is directed toward the plurality of fins by the first fan unit and directed away from the plurality of fins by the second fan unit. In some examples, the first fan unit can circulate forced-air as a non-liquid cooling medium along the heat sink. In some examples, the first fan unit and the second fan unit can be operable upon detecting electric vehicle charging. In some examples, a dielectric can be positioned proximate to the heat sink. Heat generated during electric vehicle charging can be transferred from the dielectric to the heat sink.

Non-limiting examples of the present disclosure provide methods of operating electric vehicle charging adaptors having integrated cooling systems and methods of operating integrated cooling systems for electric vehicle charging adaptors. The methods may include drawing air from outside the charging adaptor, directing air along at least one heat sink within the charging adaptor to dissipate heat or cool charging components (e.g., charging plug, charging socket, electrical conductors associated with these components), exhausting air out of the charging adaptor, and repeating these operations continuously or intermittently during electric vehicle charging.

The above summary is not intended to describe each illustrated example or every implementation of the subject matter hereof. The figures and the detailed description that follow more particularly exemplify various examples.

### BRIEF DESCRIPTION OF THE DRAWING

Subject matter hereof may be more completely understood in consideration of the following detailed description of various examples in connection with the accompanying figures, in which:

FIG. 1A is a front perspective view of a charging adaptor with integrated cooling, according to examples of the present disclosure;

FIG. 1B is a rear perspective view of the charging adaptor with integrated cooling of FIG. 1A;

FIG. 2A is a bottom view of the charging adaptor with integrated cooling of FIG. 1A;

FIG. 2B is a top view of the charging adaptor with integrated cooling of FIG. 1A;

FIG. 2C is a left side view of the charging adaptor with integrated cooling of FIG. 1A;

FIG. 2D is a right side view of the charging adaptor with integrated cooling of FIG. 1A;

FIG. 2E is a front view of the charging adaptor with integrated cooling of FIG. 1A;

FIG. 2F is a rear view of the charging adaptor with integrated cooling of FIG. 1A;

FIG. 3A is an exploded view of the charging adaptor with integrated cooling of FIG. 1A;

FIG. 3B is a right side exploded view of the charging adaptor with integrated cooling of FIG. 3A;

FIG. 3C is a partial exploded view of the charging adaptor with integrated cooling of FIG. 3A;

FIG. 3D is a side partial exploded view of the charging adaptor with integrated cooling of FIG. 3A;

FIG. 4 is a perspective view of an integrated cooling system used with the charging adaptor of FIG. 1A, the integrated cooling system comprising first and second fan units proximate a heat sink, according to examples of the present disclosure;

FIG. 5A is a cross-section view of the charging adaptor with integrated cooling of FIG. 2C, taken along cross-section line A-A;

FIG. 5B is a cross-section view of the charging adaptor with integrated cooling of FIG. 2E, taken along cross-section line C-C;

FIG. 5C is a cross-section view of the charging adaptor with integrated cooling of FIG. 2D, taken along cross-section line B-B;

FIG. 6A is a schematic diagram of the charging adaptor with integrated cooling of FIG. 1A, positioned between an electric vehicle charger and an electric vehicle;

FIGS. 6B and 6C are schematic diagrams of the charging adaptor with integrated cooling of FIG. 1A, illustrating air directed perpendicular to the direction of electric current transfer between an electric vehicle charger and an electric vehicle; and

FIG. 7 is a block diagram of the charging adaptor with integrated cooling of FIG. 1A.

While various examples are amenable to various modifications and alternative forms, specifics thereof have been shown by way of example in the drawings and will be described in detail. It should be understood, however, that the intention is not to limit the claimed inventions to the particular examples described. On the contrary, the intention is to cover all modifications, equivalents, and alternatives falling within the spirit and scope of the subject matter as defined by the claims.

### DETAILED DESCRIPTION OF THE DRAWING

Examples of the present disclosure include charging adaptors for coupling charging station charging modalities and electric vehicles, including certain incompatible charging modalities and vehicles, during electric vehicle charging. Specifically, charging adaptors of the present disclosure can be used as an intermediate coupling placed between an electric vehicle charging modality and a charging inlet of an electric vehicle that may otherwise be incompatible. This could be a charging modality designed according to a different charging standard than the electric vehicle, or vice versa. There are several charging standards used throughout the world which can lead to many situations where incompatible charging modalities and electric vehicles may be encountered. These standards include SAE J1772 (Type 1), Mennekes (Type 2), North American Charging Standard (NACS), Combined Charging System (CCS) Combo 1 (CCS1), CCS Combo 2 (CCS2), Megawatt Charging System (MCS), CHAdeMO, GB/T (e.g., GB/T 20234), and others.

Charging adaptors of the present disclosure enable the use of a charging modality designed according to one standard to be used to charge electric vehicles designed according to a different standard. This can be, for example, a J1772 charging modality with a NACS charging inlet-based electric vehicle, an NACS charging modality with a CCS1 or CCS2 charging inlet-based electric vehicle, a CCS1 or CCS2 charging modality with a CHAdeMO charging inlet-based electric vehicle, or vice versa any of these arrangements. Other charging standard arrangements are also contemplated by the present disclosure. Charging adaptors of the present disclosure may also be used with compatible charging modalities and vehicles designed according to the same charging standards (e.g., an NACS charging modality with an NACS charging inlet-based electric vehicle).

Charging adaptors of the present disclosure may include integrated cooling in the form of a forced-air cooling system that addresses heat dissipation challenges encountered during charging. As electric vehicles require substantial current to recharge their batteries, significant heat can be generated in the conductors, plugs, and sockets of charging adaptors, especially when adapting between different charging standards or modes. The disclosed charging adaptors include a housing with one or more fan units and at least one heat sink configured to absorb heat generated during electric vehicle charging to cool one or more electrical contacts (e.g., charging plug(s), charging socket, and electrical conductors included with these components). The system may use one or more vents defined in the housing and a combination of intake and exhaust fans, such as a first intake fan unit and a second exhaust fan unit of the one or more fan units, to establish a pressure differential between a hollow internal region of the housing and the outside environment. This can enable efficient forced-air cooling without relying on liquid coolants or other non-forced-air cooling processes. In some examples, heat generated during charging may be transferred first from one or more electrical contacts to a heat-conducting dielectric positioned within the housing, and then to a heat sink positioned proximate to the dielectric where the heat can be dissipated using the fan unit(s).

Advantages of the present disclosure include improved thermal management within the charging adaptor and enhanced safety, reliability, and compatibility for electric vehicle charging across various charging infrastructures. Other advantages of the present disclosure will become apparent based on the accompanying figures and the corresponding description in reference to certain examples illustrated in the figures.

Before turning to the figures, which illustrate certain examples in detail, it should be understood that the present disclosure is not limited to the details or methodology set forth in the description or illustrated in the figures. It should also be understood that the terminology used herein is for the purpose of description only and should not be regarded as limiting. Common definitions are generally intended for the terminology used herein unless a specific definition is provided. In the case of a term having a common definition and a specific definition provided herein, the term should be construed according to its specific definition.

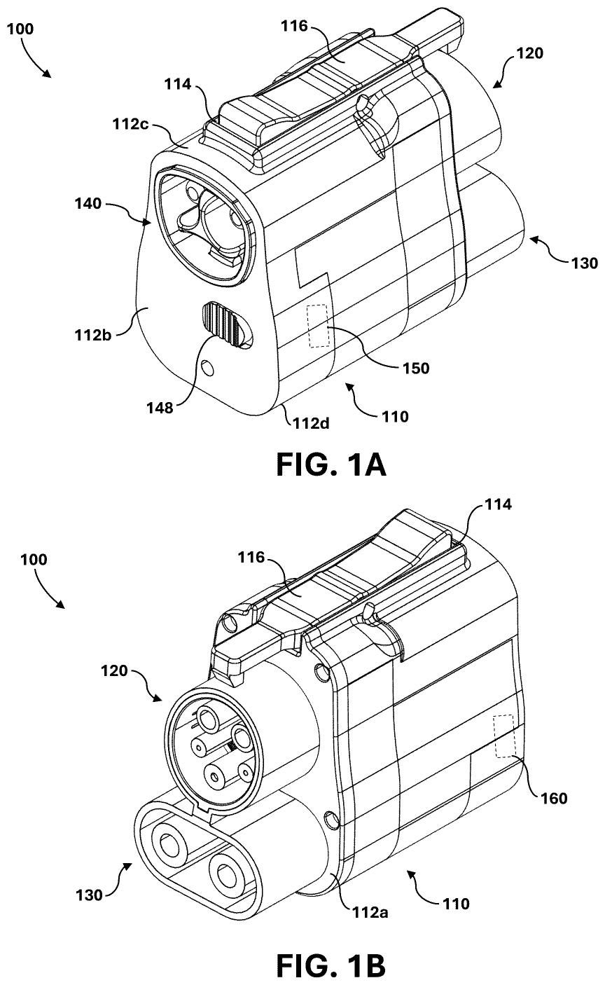

FIGS. 1A and 1B depict front and rear perspective views, respectively, of a charging adaptor 100 with integrated cooling, according to examples of the present disclosure. Charging adaptor 100 can act as an intermediate coupling between various charging station charging modalities, such as charging cables, and a charging inlet of an electric vehicle that may otherwise be incompatible. Accordingly, charging adaptor 100 enables the interchangeable use of several different charging standards used by charging modalities and electric vehicles. Charging adaptor 100 also provides integrated cooling to prevent overheating of electrical components used during charging. For the sake of clarity, charging adaptor 100 can be a separate component not included with the charging modality and the electric vehicle in their original manufactured states. Rather, charging adaptor 100 can enable integrated cooling which may be transferred to the charging modality and the electric vehicle using the techniques described herein.

Charging adaptor 100 can include a housing 110 extending horizontally or lengthwise between a first end 112a and a second end 112b. A first charging plug 120 and a second charging plug 130 can be arranged along and coupled to a surface defining first end 112a. Charging plug 120 can be arranged above charging plug 130 along the surface of first end 112a. For example, charging plugs 120 and 130 can be vertically or substantially vertically aligned along the surface of first end 112a as illustrated in FIG. 1B. A charging socket 140 can be defined within an opening along a surface defining second end 112b as illustrated in FIG. 1A. Charging plug 120, charging plug 130, and/or charging socket 140 may be referred to as “one or more electrical contacts” of charging adaptor 100 throughout the present disclosure. The opening that contains charging socket 140 may be defined proximate to a top surface 112c and distal from a bottom surface 112d of housing 110, in a horizontal or substantially horizontal alignment opposite charging plug 120. A lock mechanism 148 may be positioned along the surface defining second end 112b proximate to bottom surface 112d and distal from top surface 112c (e.g., below charging socket 140 in a horizontal or substantially horizontal alignment opposite charging plug 130).

Housing 110 may define an elongated groove 114 at least partially along top surface 112c. A release latch 116 may be received at least partially within elongated groove 114. Release latch 116 can be configured to uncouple charging adaptor 100 from a charging inlet of an electric vehicle when charging is complete. This can be achieved by applying a downward force to a portion of release latch 116 positioned within groove 114, proximate to second end 112b.

Housing 110 may further define one or more vents 118 that provide an opening between a hollow internal region of housing 110 and the external environment. Vent(s) 118 may be arranged in any suitable location(s) between and/or around first and second ends 112a and 112b and top and bottom surfaces 112c and 112d of housing 110. In some examples, vent(s) 118 may be defined in bottom surface 112d of housing proximate to charging socket 140. Specifically, vent(s) 118 can include a first vent 118 and a second vent 118 defined as elongated openings in bottom surface 112d. Vent(s) 118 may be configured to cooperate with one or more fan units, for example first and second fan units 150 and 160, as described further in reference to subsequent figures.

In some examples, at least one vent 118 can be defined at or proximate to locations where first and second fan units 150 and 160 are located within housing 110 (e.g., a vent 118 provides an opening adjacent to each of first and second fan units 150 and 160). For example, a first vent 118 can be defined adjacent to or proximate to first fan unit 150 on a first side of housing 110, while a second vent 118 can be defined adjacent to or proximate to second fan unit 160 on a second side of housing 110. The first and second sides of housing 110 may be opposite each other in a direction perpendicular to a direction between first and second ends 112a and 112b. In some examples, first and second vents 118 can be defined in bottom surface 112d of housing 110 proximate to charging socket 140. Generally, vent(s) 118 may comprise any shape or size sufficient to enable air to be drawn into housing 110 or to be exhausted out of housing 110 by first and second fan units 150 and 160, respectively. In some examples, vent(s) 118 can comprise any geometric cross-sectional shape including circular, rectangular, triangular, oval, elliptical, other polygonal shapes, various non-polygonal shapes, and combinations thereof.

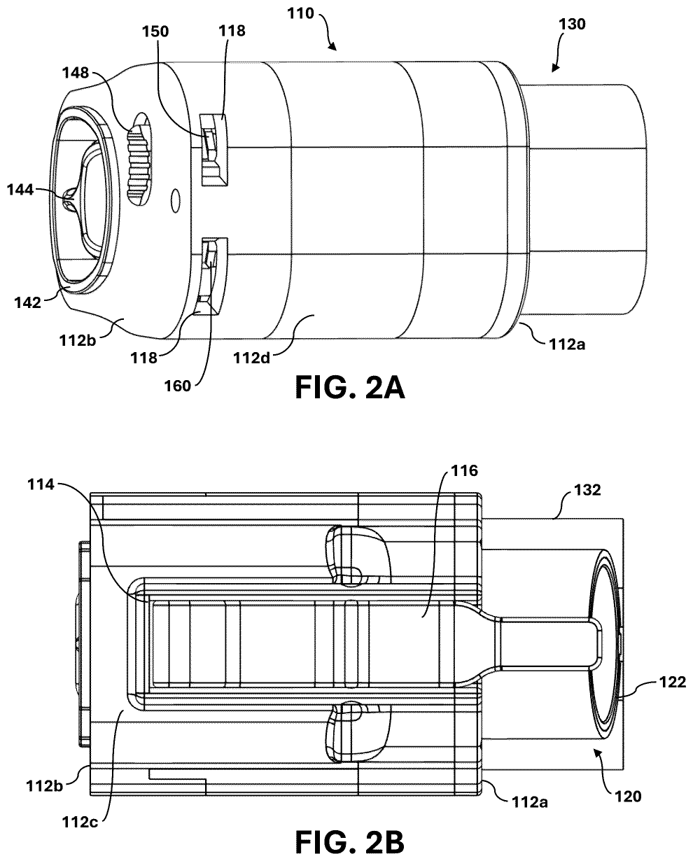

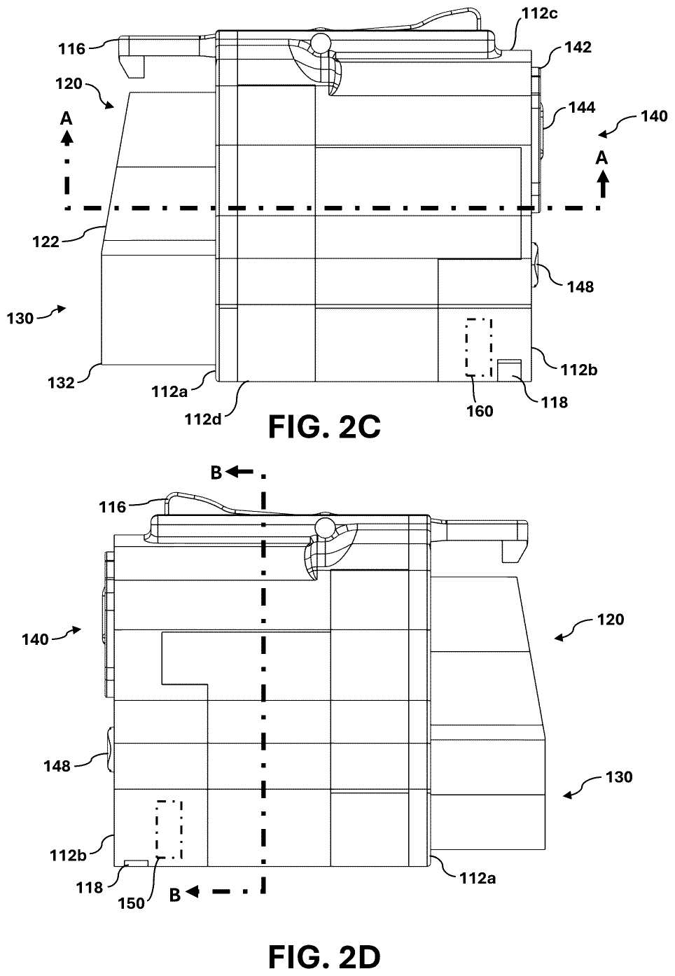

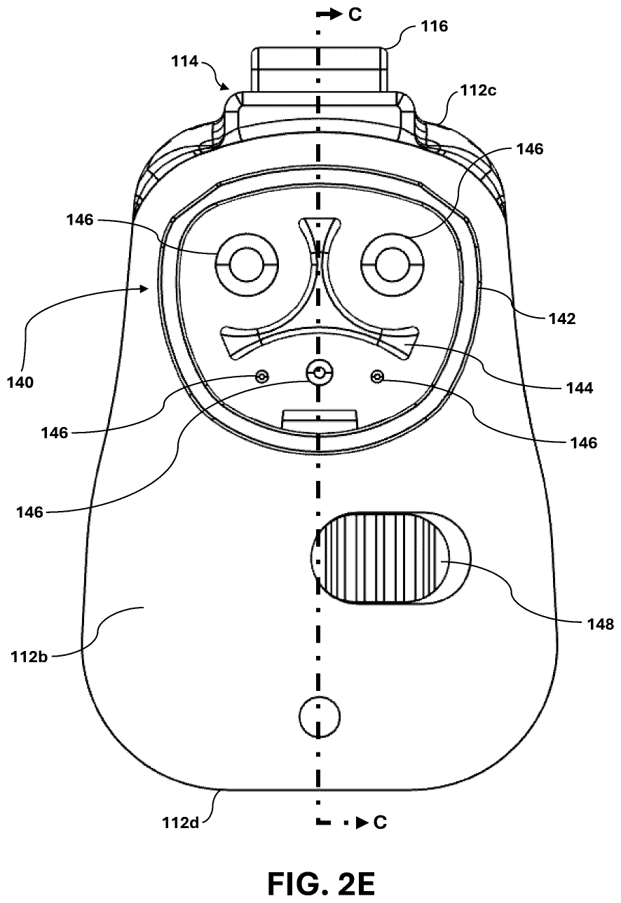

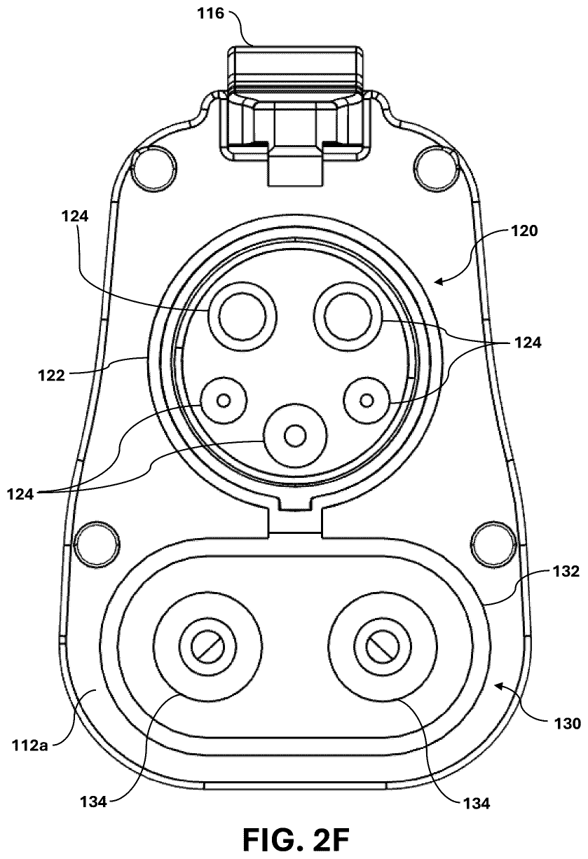

FIGS. 2A through 2F depict various additional views of charging adaptor 100. Specifically, a bottom view of charging adaptor 100 is depicted in FIG. 2A, a top view of charging adaptor 100 is depicted in FIG. 2B, a left side view of charging adaptor 100 is depicted in FIG. 2C, a right side view of charging adaptor 100 is depicted in FIG. 2D, a front view of charging adaptor 100 is depicted in FIG. 2E, and a rear view of charging adaptor 100 is depicted in FIG. 2F.

As illustrated, housing 110 can extend between ends 112a and 112b and along surfaces 112c and 112d. Housing 110 can define a groove 114 in at least a portion of surface 112c for receiving release latch 116. Housing 110 can further define one or more vents 118 arranged in any suitable location proximate to or adjacent first and second fan units 150 and 160. For example, at least one vent 118 can be defined in a first side surface of housing 110, as illustrated in FIG. 2C, and at least one vent 118 can be defined in a second side surface of housing 110, as illustrated in FIG. 2D. The first side surface may be opposite the second side surface in a direction perpendicular to a direction extending between first and second ends 112a and 112b. In some examples, first and second vents 118 can be defined in bottom surface 112d of housing 110 proximate to charging socket 140. First and second vents 118 can each have an elongated shape and can be spaced-apart along first or second sides, or along bottom surface 112d in locations proximate to end 112b.

Each vent 118 may define an opening between a hollow internal region of housing 110 and the external environment. Vent(s) 118 may allow air from the outside environment to be drawn into housing 110 using at least one intake fan unit, for example a first fan unit 150 positioned within housing 110. Vent(s) 118 may also allow air to be exhausted back to the outside environment from housing 110 using at least one exhaust fan unit, for example a second fan unit 160 positioned within housing 110.

In some examples, housing 110 may comprise two or more removably couplable portions that can be secured together using fasteners, adhesives, or another coupling mechanism. Providing a housing 110 with two or more removably couplable portions enables access to the hollow internal region of housing 110 when the portions are separated. This may be useful when diagnosing any operational issues with charging adaptor 100 or when replacing or inspecting components within housing 110 (e.g., when inspecting first and second fan units 150 and 160). In some examples, housing 110 may be manufactured from one or more of a variety of materials including metals, polymers, composites, ceramics, or combinations thereof.

First charging plug 120, which may be characterized as a “first electrical contact,” can be coupled to a charging station charging modality and configured to transfer electric current through charging adaptor 100 to an electric vehicle. Charging plug 120 may include a plug housing 122 that contains a plurality of conductors 124, for example five conductors 124 arranged in a circle. Plug housing 122 may define a circular geometry that extends outward from end 112a, generally proximate to top surface 112c and above second charging plug 130. In other examples, plug housing 122 may define a variety of other geometrical shapes including oval, rectangular, triangular, elliptical, other polygonal shapes, various non-polygonal shapes, and combinations thereof. Generally speaking, plug housing 122 can be designed with enough space to contain conductors 124 with or without a gap between adjacent conductors 124 and the inner wall(s) of housing 122.

Conductors 124 may extend from a hollow internal region of housing 110 through at least a portion of plug housing 122. Conductors 124 can enable the transfer of electric current, originally received from a charging modality attached to charging adaptor 100, to an electric vehicle. Conductors 124 may include various mechanical and/or electrical components as needed to enable the transfer of electric current. Such components may include conducting wires, terminal connectors, relays or contactors, conduits, fuses or circuit breakers, temperature sensors, control circuitry, resistors, capacitors, and others as needed. These components are generally positioned within housing 110 but may also be positioned within plug housing 122 or within conductors 124. The selection of such components is within the skill of one of ordinary skill in the art of the present disclosure.

In combination with first charging plug 120, second charging plug 130, which may be characterized as a “second electrical contact,” can be coupled to a charging station charging modality and configured to transfer electric current through charging adaptor 100 to an electric vehicle. Charging plug 130 may include a plug housing 132 that contains a plurality of conductors 134, for example two conductors 134 arranged in a row. Plug housing 132 may define an oval-shaped geometry that extends outward from end 112a, generally proximate to bottom surface 112d and below plug housing 122. In other examples, plug housing 132 may define a variety of other geometrical shapes including circular, rectangular, triangular, elliptical, other polygonal shapes, various non-polygonal shapes, and combinations thereof. Like plug housing 122, plug housing 132 can be designed with enough space to contain conductors 134 with or without a gap between adjacent conductors 134 and the inner wall(s) of housing 132.

Similar to conductors 124, conductors 134 of charging plug 130 may extend from a hollow internal region of housing 110 through at least a portion of plug housing 132. Conductors 134 can enable the transfer of electric current, originally received from a charging modality attached to charging adaptor 100, to an electric vehicle. This can be done in combination with the transfer of electric current from conductors 124 of charging plug 120. Conductors 134 may include various mechanical and/or electrical components as needed, some of which are depicted in later figures, to enable the transfer of electric current. These components may include conducting wires, terminal connectors, relays or contactors, conduits, fuses or circuit breakers, sensors, control circuitry, resistors, capacitors, and others as needed. Such components are generally positioned within housing 110 but may also be positioned within plug housing 132 or within conductors 134 as needed. The selection of such components is within the skill of one of ordinary skill in the art of the present disclosure.

In some examples, charging plugs 120 and 130, collectively characterized as “first and second electrical contacts” or “one or more electrical contacts,” may be integrally formed as a single charging plug comprising all or some of housings 122 and 132 and conductors 124 and 134. The combined charging plug can be coupled to a charging modality and can be configured to transfer electric current to an electric vehicle as described previously (e.g., transferring electrical current from the modality through charging adaptor 100 and to the vehicle). Charging plugs 120 and 130, or a combined charging plug or “electrical contact” in some examples, may be designed in accordance with different charging standards and thus may vary in the arrangement of housings 122 and 132 and conductors 124 and 134. For example, charging modalities or charging inlet-based electric vehicles designed according to the CHAdeMO or GB/T standards may require a different number or arrangement of conductors 124 and 134 within each housing 122 and 132 compared to the NACS or CCS standards. The design of housings 122 and 132 may also be different to accommodate other charging standards (e.g., housings 122 and 132 may comprise different geometrical shapes).

Charging socket 140, which may be characterized as a “third electrical contact,” can be coupled to an electric vehicle charging inlet and configured to transfer electrical current received from the charging station charging modality to the vehicle. Charging socket 140 may include a socket housing 142 surrounding a connector 144 and a plurality of conductors 146, for example five conductors 146 arranged in two or more spaced-apart rows (e.g., a first row of three conductors 146 and a second row of two conductors 146). Socket housing 142 may define a combined rectangular and circular geometry that extends outward from end 112b, generally proximate to top surface 112c. In other examples, socket housing 142 may define a variety of other geometrical shapes including oval, triangular, elliptical, other polygonal shapes, various non-polygonal shapes, and combinations thereof. Socket housing 142 can be designed with enough space to contain connector 144 and conductors 146 with or without gaps between connector 144, adjacent conductors 146, and the inner wall(s) of housing 142.

Connector 144 can comprise a projection configured to interface with an opening defined in an electric vehicle charging inlet for securely coupling charging socket 140 to the inlet. Connector 144 generally extends outward starting at or near a midpoint of charging socket 140. In some examples, connector 144 can include three elongated sections that connect at or near the midpoint. Each pair of elongated sections may curve inward or be convex relative to one or more conductors 146. For example, a first pair of adjacent elongated sections may curve inward relative to a first conductor 146, a second pair of adjacent elongated sections may curve inward relative to a second conductor 146, and a third pair of adjacent elongated sections may curve inward relative to third, fourth, and fifth conductors 146. Other arrangements for connector 144 and conductors 146 are also contemplated by the present disclosure, for example more than three elongated sections for connector 144 and different placements or groupings of conductors 146.

Like other conductors described herein, conductors 146 of charging socket 140 may extend from a hollow internal region of housing 110 through at least a portion of socket housing 142. Conductors 146 can enable the transfer of electric current to an electric vehicle for charging. Conductors 146 may include various mechanical and/or electrical components as needed to enable the transfer of electric current. These components may include conducting wires, terminal connectors, relays or contactors, conduits, fuses or circuit breakers, temperature sensors, control circuitry, resistors, capacitors, and others as needed. Such components are generally positioned within housing 110 but may also be positioned within socket housing 142 or within conductors 146. The selection of such components is within the skill of one of ordinary skill in the art of the present disclosure.

In some examples, charging plug 120, charging plug 130, and/or charging socket 140 may be collectively characterized as “one or more electrical contacts” that enable the transfer of electric current from a charging modality through charging adaptor 100 and to an electric vehicle. In some examples, a lock mechanism 148 may be positioned at end 112b. Lock mechanism 148 can be actuated between a locked position and an unlocked position to, respectively, lock and unlock the coupling of charging socket 140 to the electric vehicle inlet. This provides a simple but effective mechanism to securely attach charging socket 140 to the vehicle inlet during charging. The unlocked position is illustrated throughout the figures.

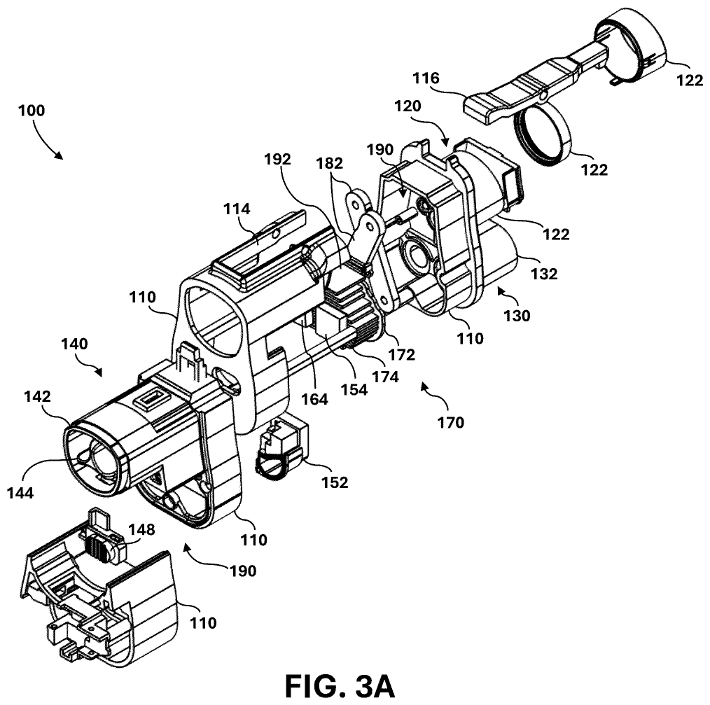

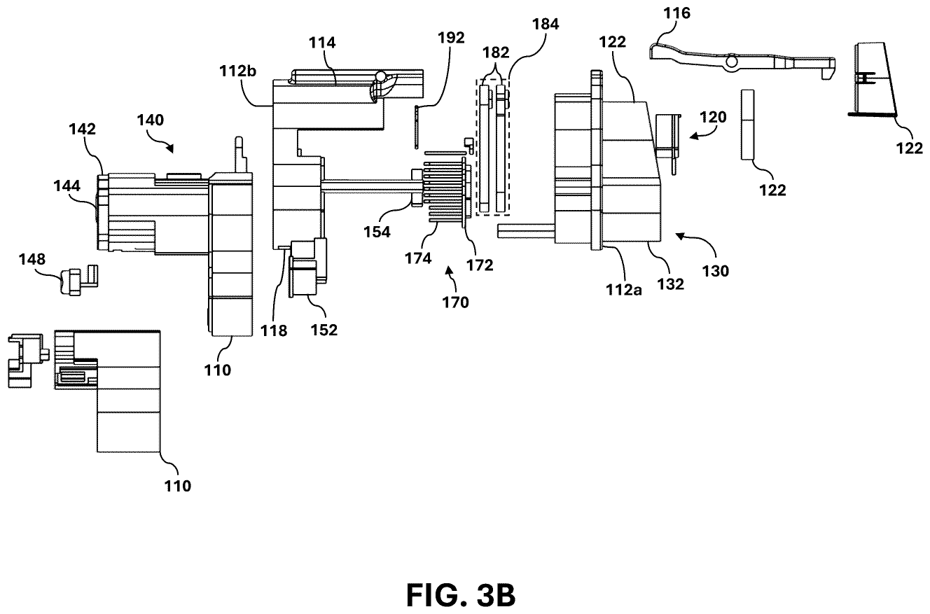

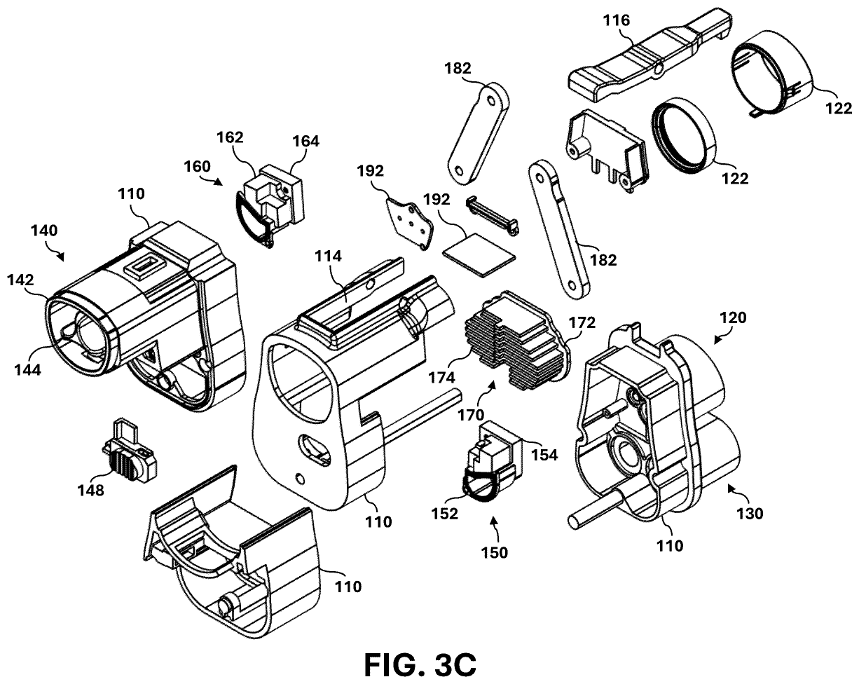

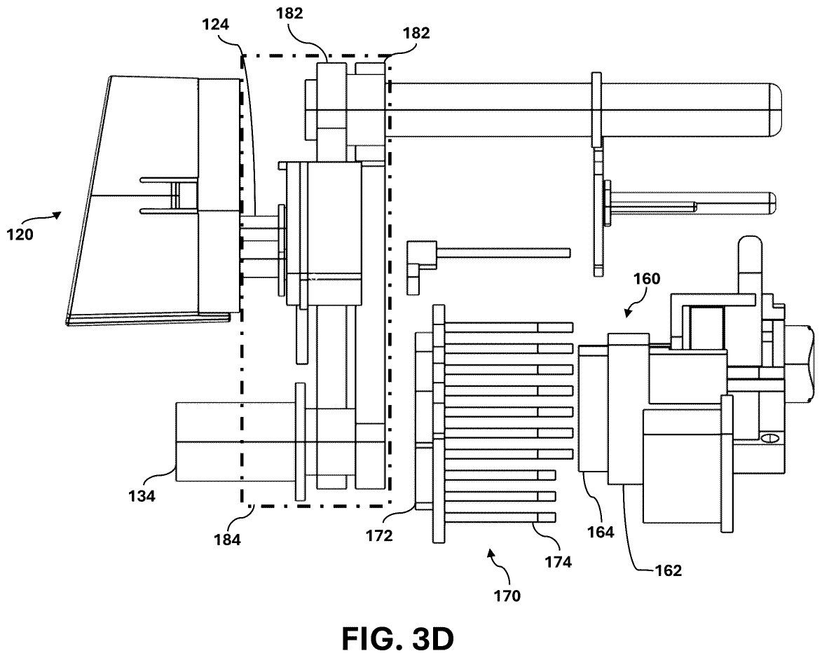

Charging adaptor 100 can also include at least one fan unit 150 or 160 positioned within the hollow internal region of housing 110. In some examples, the at least one fan unit 150 or 160 can comprise a first fan unit 150 and a second fan unit 160. Other examples may include three or more fan units 150 or 160. First fan unit 150 may include a duct 152 operably coupled to a fan 154. Second fan unit 160 may also include a duct 162 operably coupled to a fan 164. Fans 154 and 164 are generally non-liquid, forced-air fans that can direct air along at least one heat sink (depicted starting with FIG. 3A) positioned within housing 110 to cool electrical components during electric vehicle charging. The at least one heat sink can receive heat generated during charging from a heat-conducting dielectric (depicted starting with FIG. 3A) positioned within housing 110.

In other examples, fans 154 and 164 can be axial fans, centrifugal or radial fans, crossflow or tangential fans, bladeless fans, mixed flow fans, propellor fans, forward curved fans, and/or inline duct fans. In some examples, the at least one fan unit or first and second fan units 150 and 160 can be powered by at least one of an electrical power source positioned within housing 110 and a battery. The electrical power source may comprise an internal power line such as a 5V internal proximity line located within housing 110. The battery may be rechargeable using a wired recharger or a wireless recharger. The battery may also be replaced when expired or low capacity.

In operation, first fan unit 150, which can be characterized as an intake fan, can draw air from the outside environment into housing 110 through one or more vents 118 positioned proximate to or adjacent fan unit 150. This can represent an intake of air at a positive pressure. First fan unit 150 can then direct the air along at least one heat sink positioned within housing 110. Because the at least one heat sink absorbs heat generated during electric vehicle charging, directing air along the heat sink(s) enables cooling of one or more electrical contacts of charging adaptor 100, for example first and second charging plugs 120 and 130 and charging socket 140. Air may be continuously or intermittently drawn in and directed along the heat sink(s) using first fan unit 150 while electric vehicle charging occurs. At the same time, air from first fan unit 150 can be exhausted out of housing 110 using second fan unit 160, which can be characterized as an exhaust fan, through one or more vents 118 positioned proximate to or adjacent fan unit 160. This can represent an exhaust of air at a negative pressure. Accordingly, first and second fan units 150 and 160 can generate a pressure differential that facilitates the transfer of air into housing 110 using first intake fan unit 150, and out of housing 110 using second exhaust fan unit 160.

In some examples, first and second fan units 150 and 160 can be integrated into a single intake-exhaust fan unit configured to perform the functions of both fan units 150 and 160. For example, a single fan unit 150 or 160 can be configured both to draw outside air into housing 110 through vent(s) 118 and to exhaust air out of housing 110 through the same or different vent(s) 118 (e.g., vent(s) 118 defined in bottom surface 112d of housing proximate to end 112b). The single fan unit 150 or 160 can create a pressure differential using drawn air at a positive pressure and exhausted air at a negative pressure. In some examples, first and second fan units 150 and 160 can be operable only upon detecting that electric vehicle charging is occurring. This may be achieved, for example, using one or more sensors configured to detect when charging is occurring and one or more processors configured to activate first fan unit 150 and second fan unit 160 upon receiving an indication from the sensor(s) that charging is occurring. The sensor(s) and the processor(s) may be included with charging adaptor 100, for example within housing 110 or external to charging adaptor 100 (e.g., sensor(s) included with the charging modality or the electric vehicle can be in wireless communication with processor(s) communicatively coupled to first and second fan units 150 and 160).

FIG. 3A depicts an exploded view of charging adaptor 100 illustrating external and internal components included with adaptor 100. This exploded view illustrates the general arrangement of components included with charging adaptor 100, including housing 110, first and second charging plugs 120 and 130, charging socket 140, first and second fan units 150 and 160, heat sink 170, and conductor straps 182, along with their constituent components, elements, and features described previously. It should be noted that this exploded view does not necessarily provide the exact positions, configurations, or sizes of the illustrated components of charging adaptor 100. Rather, some components may be illustrated in different positions or configurations, or with different sizes, than what is generally used when charging adaptor 100 is assembled.

Starting with FIG. 3A, charging adaptor 100 may also include conductor straps 182 positioned within housing 110. Conductor straps 182 can be used to securely hold at least some of conductors 124, 134, and/or 146 within housing 110. Each conductor strap 182 may have a slotted geometry that can define an aperture at opposing ends. A pair of conductor straps 182 may cross over each other at least partially when assembled within housing 110, thereby forming an X-like shape in combination.

Charging adaptor 100 may also include various mechanical and/or electrical components 190 generally positioned within housing 110 but also externally located as needed. These components 190 may include at least one circuit board 192 with associated electrical parts. Circuit board(s) 192 may be used to control various electrical components, including first and second charging plugs 120 and 130, charging socket 140, and first and second fan units 150 and 160. For example, circuit board(s) 192 may control operation of first and second fan units 150 and 160 during electric vehicle charging. In some examples, circuit board(s) 192 can enable operation of first and second fan units 150 and 160 during charging, and can disable operation when charging is complete or when charging is paused or stopped. Circuit board(s) 192 may be positioned in any suitable location within housing 110.

FIG. 3A also illustrates the modularity of housing 110 in that it can include two or more removably coupled pieces or portions. This can provide access to the hollow internal region of housing 110 if needed for repairs, component replacements, or other general maintenance procedures, for example. Housing 110 may comprise a modular configuration with two or more removably coupled pieces, or a configuration where housing 110 comprises one or more integrally formed pieces or portions that are generally irremovable.

FIGS. 3B through 3D depict right side, partial exploded, and partial side views, respectively, of charging adaptor 100 as shown in the exploded view of FIG. 3A. These figures present various perspectives and arrangements of the components of charging adaptor 100 described previously. These figures may depict fewer components than earlier illustrations. This selective representation is intended solely to highlight specific details of charging adaptor 100 and should not be construed as limiting in any way.

FIGS. 3B and 3D also illustrate a heat-conducting dielectric 184 positioned within housing 110, with the dielectric 184 at least partially surrounding conducting straps 182. The material of dielectric 184 may be flowed into housing 110 during manufacturing as a liquid or soft solid and subsequently hardened into its final shape. In some examples, dielectric 184 may comprise a thermoset material such as an epoxy resin. Dielectric 184 can be used to isolate the positive and negative high voltage conductors within housing 110, namely conductors 124 and 134, to prevent electrical arcing during use. Dielectric 184 can also act as a sealant for conductors 124 and 134 to prevent water ingress into the region proximate charging plugs 120 and 130. This can enable charging adaptor 100 to be used when it is raining or to be left outside for extended periods of time (e.g., left outside at a charging station). Dielectric 184 may also be positioned proximate to or in direct contact with heat sink 170 to enable heat transfer first from charging plugs 120 and 130 to dielectric 184 and then to heat sink 170 from dielectric 184. The absorbed heat can then be dissipated using first and second fan units 150 and 160 as described previously.

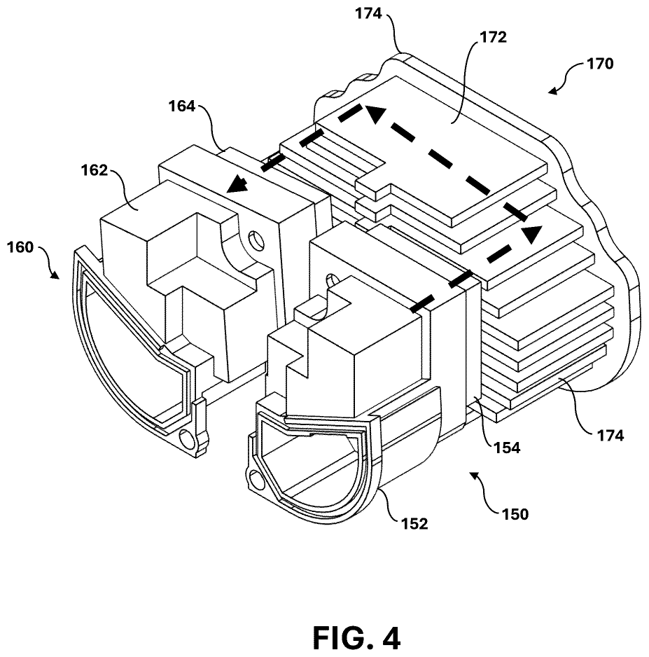

FIG. 4 depicts a perspective view of an integrated cooling system used with charging adaptor 100. The integrated cooling system can include first and second fan units 150 and 160 and at least one heat sink 170 having a mount plate 172 and a plurality of fins 174 extending outward from mount plate 172. Heat generated during electric vehicle charging can be absorbed by heat sink 170 and dissipated using air directed at heat sink 170 from at least one fan unit, for example first fan unit 150. As noted previously, first fan unit 150 can draw outside air into housing 110 through one or more vents (not depicted in this figure) positioned proximate to or adjacent fan unit 150. The outside air can then be directed toward heat sink 170 using first fan unit 150 where it moves along and around fins 174.

Second fan unit 160 can receive the outside air after it moves along heat sink 170. Second fan unit 160 can then exhaust the outside air back to the outside environment through one or more vents (not depicted in this figure), so that cooled air is continuously circulated along heat sink 170 and within housing 110. This enables indirect cooling of first and second charging plugs 120 and 130 and charging socket 140, thereby dissipating heat at both the charging modality side and at the electric vehicle charging inlet. The integrated cooling system thus provides continuous cooling during charging without requiring separate cooling systems for the charging modality and the vehicle. Additionally, the integrated cooling system achieves continuous cooling without using a liquid cooling medium as found in certain conventional cooling systems.

It is noted that a heat-conducting dielectric (not depicted in this figure) may be positioned proximate to or adjacent mount plate 172 in some examples of the integrated cooling system. Heat can be transferred first from one or more electrical contacts, such as charging plugs 120 and 130, to the dielectric, and then from the dielectric to mount plate 172 and fins 174 where the heat can be dissipated using air circulated along heat sink 170 by first fan unit 150. The typical air flow from first fan unit 150 along heat sink 170 and toward second fan unit 160 for exhausting is illustrated using arrows in FIG. 4. It is noted that air may flow in the opposite direction if the positions of first and second fan units 150 and 160 are swapped (e.g., air flowing from the current position of second fan unit 160 to the current position of first fan unit 150 along heat sink 170).

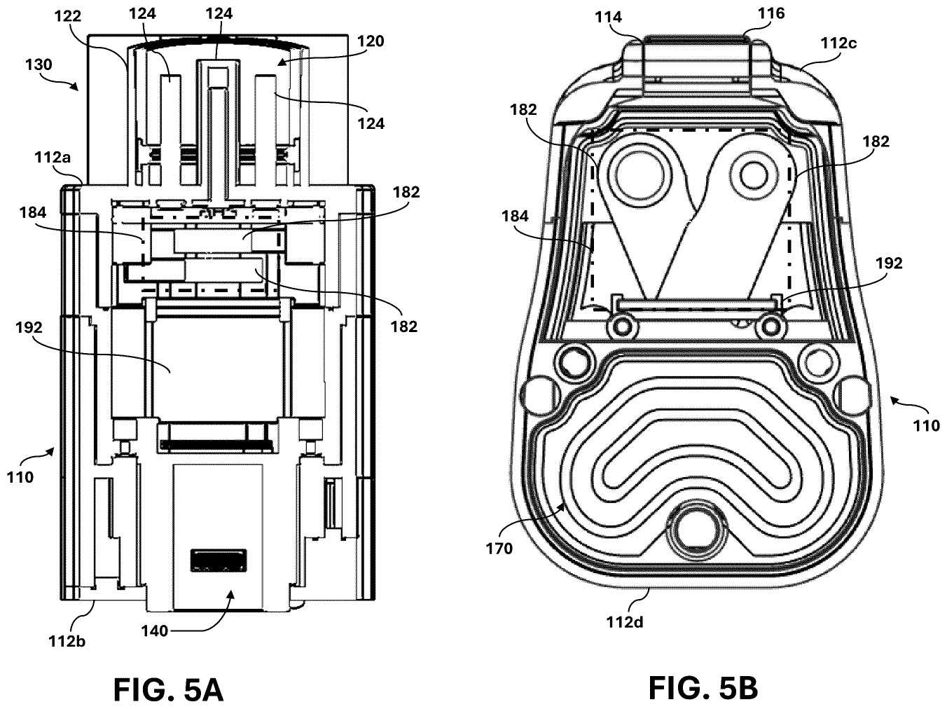

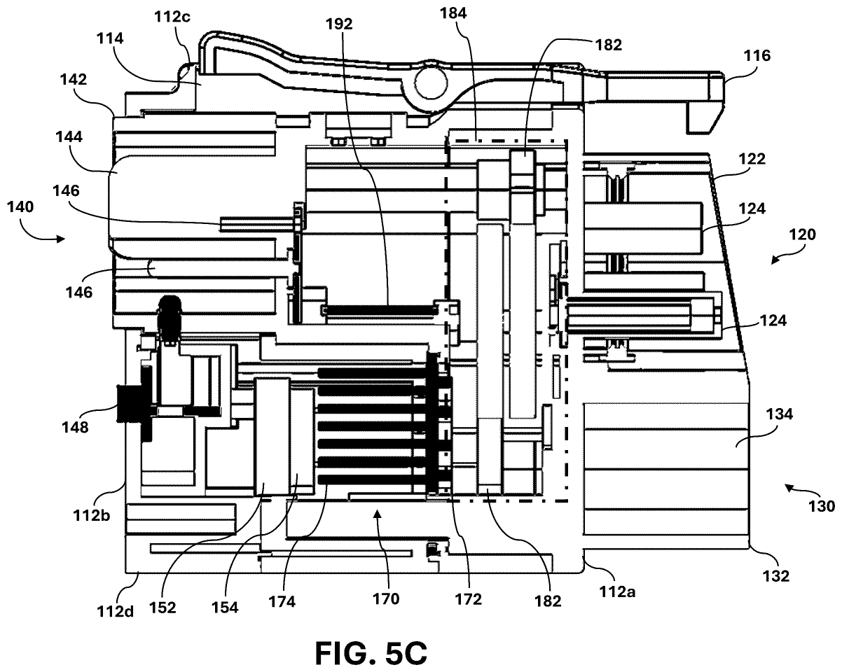

FIG. 5A depicts a cross-section view of charging adaptor 100 taken along cross-section line A-A from FIG. 2C. This view depicts housing 110 extending horizontally between ends 112a and 112b, with first and second charging plugs 120 and 130 positioned at end 112a and charging socket 140 positioned at end 112b. A circuit board 192 is positioned approximately equidistant between ends 112a and 112b. Two conductor straps 182, positioned proximate to end 112a, have a slightly offset alignment because of their partial crossover or X-like shape when combined within housing 110. Conductors 124 of charging plug 120 are shown extending from housing 110 to positions partially within plug housing 122. Heat-conducting dielectric 184 is shown positioned around conductor straps 182 and other components within housing 110. As illustrated, dielectric 184 can be positioned proximate to or adjacent a heat sink (not explicitly depicted in this figure because it is positioned generally underneath circuit board 192). Dielectric 184 can be configured to transfer heat from one or more electrical contacts, such as charging plugs 120 and 130, to the heat sink for dissipation therefrom using at least one fan unit (not depicted in this figure).

FIG. 5B depicts a cross-section view of charging adaptor 100 taken along cross-section line C-C from FIG. 2E. Housing 110 is shown extending vertically between top and bottom surfaces 112c and 112d. Heat sink 170 can be provided at a position within housing 110 that is proximate to bottom surface 112d. The partial crossover or X-like shape formed by conductor straps 182 is also shown, along with a circuit board 192 positioned approximately equidistant between surfaces 112c and 112d. Heat-conducting dielectric 184 is illustrated at least partially surrounding conductor straps 182 and being positioned proximate to or adjacent heat sink 170. Groove 114, defined partially along top surface 112c, and release latch 116, positioned at least partially within groove 114, are also shown in the cross-section view of FIG. 5B.

FIG. 5C depicts a cross-section view of charging adaptor 100 taken along cross-section line B-B from FIG. 2D. Notably, heat sink 170 with a plurality of fins 174 extending from a mount plate 172 is depicted at a position approximately equidistant between ends 112a and 112b. Fins 174 can extend outward from mount plate 172 in a direction toward duct 162 and fan 164 of second fan unit 160. While not depicted in this figure, first fan unit 150 can be provided on an opposite side adjacent and in general alignment with second fan unit 160. Accordingly, first or second fan units 150 and 160 can direct air at heat sink 170 to cool or dissipate heat transferred to fins 174 and mount plate 172 during charging. This is in addition to the processes described previously for air intake and circulation by first fan unit 150 and for air exhaust by second fan unit 160.

In some examples, first and second fan units 150 and 160 can be horizontally aligned with respect to heat sink 170, for example arranged at right angles along a length of heat sink 170. In other examples, first and second fan units can be angled with respect to heat sink 170, for example arranged at angles between 5 and 85 degrees along a length of heat sink 170. Either arrangement of first and second fan units 150 and 160 with respect to heat sink 170 can enable air to be directed toward heat sink 170 by first fan unit 150, and directed away from heat sink 170 by second fan unit 160.

Heat-conducting dielectric 184 is again shown in its proximate or adjacent position relative to heat sink 170 in FIG. 5C. During charging, heat can be generated from one or more electrical contacts such as charging plugs 120 and 130. The generated heat can be transferred to dielectric 184 from conductors 124 and 134. The generated heat can then be transferred from dielectric 184 to heat sink 170 where it can be dissipated using first and second fan units 150 and 160. Heat dissipation can occur using first fan unit 150 which directs air along and around heat sink 170, and using second fan unit 160 which exhausts the air out of housing 110 through one or more vents, after the air is directed along and around heat sink 170. In these examples or other examples, air can be circulated between first and second ends 112a and 112b and along top and bottom surfaces 112c and 112d of housing 110 using the cooling processes described for first and second fan units 150 and 160. This can be in place of or in addition to directing air along and around heat sink 170.

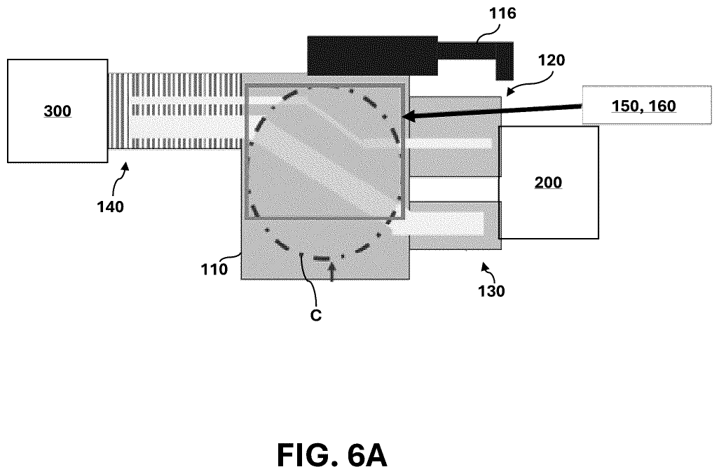

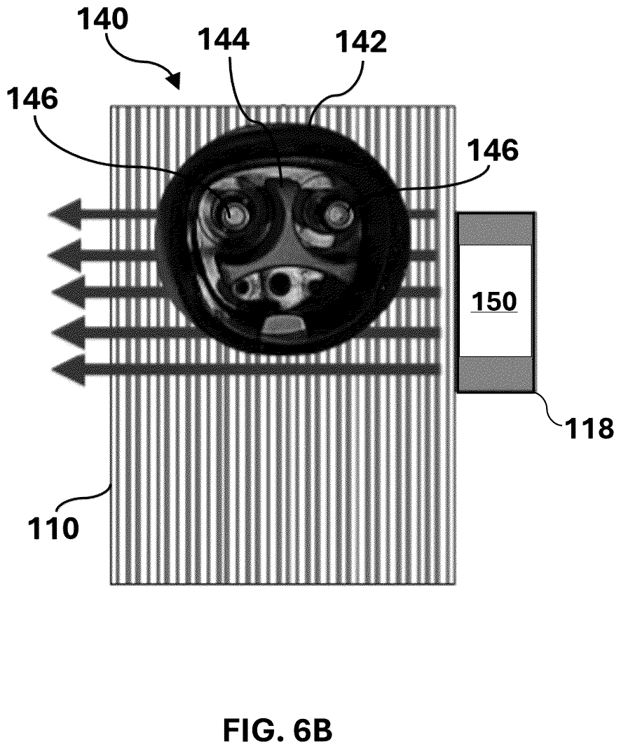

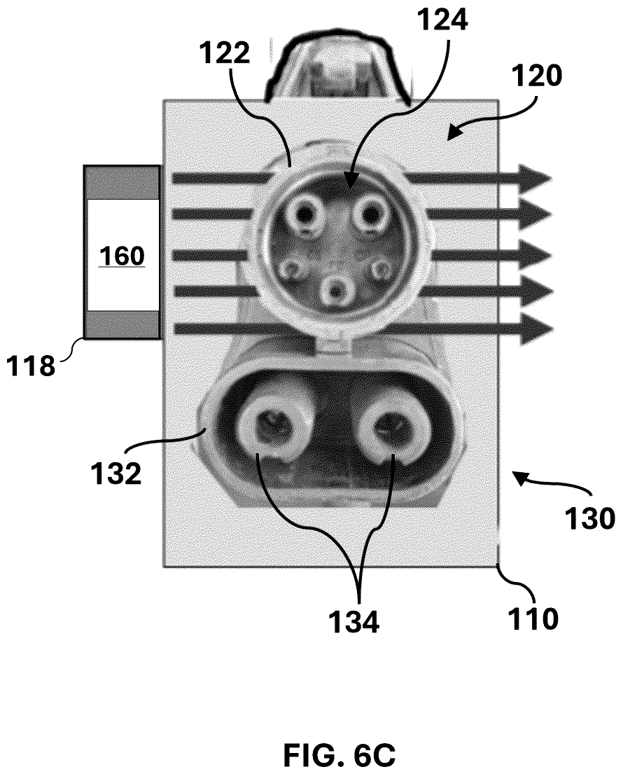

FIG. 6A depicts a schematic diagram of charging adaptor 100 positioned between an electric vehicle charger 200 and an electric vehicle 300. Charging adaptor 100 can be coupled to charger 200 via charging socket 140 and coupled to vehicle 300 via charging plugs 120 and 130. In operation, first and second fan units 150 and 160 can create a cooling zone C within housing 110 where heat is dissipated or exhausted out of housing 110 through vents 118. The cooling zone C can be defined around a heat sink (not depicted in this figure) where heat is transferred to initially from a heat-conducting dielectric. Air can be directed along the heat sink in the directions indicated in FIGS. 6B and 6C with respect to charging socket 140 and charging plugs 120 and 130, respectively.

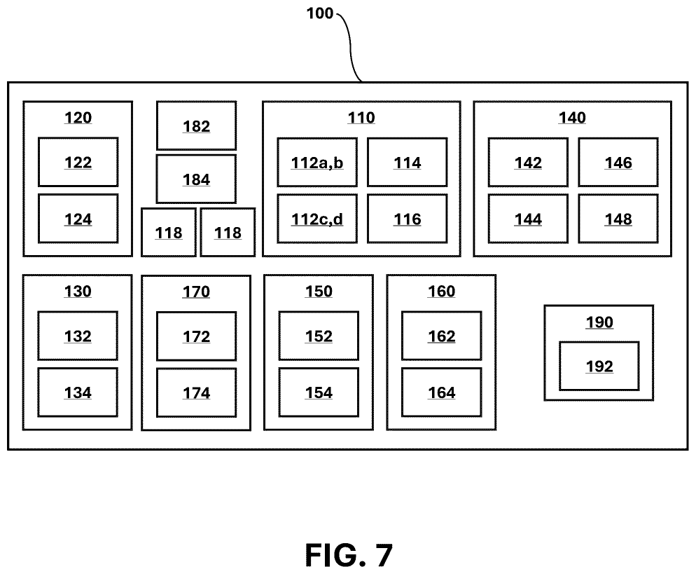

FIG. 7 depicts a block diagram of charging adaptor 100 detailing various external and internal components described previously. Charging adaptor 100 can include a housing 110 extending between first and second ends 112a and 112b and defining opposing top and bottom surfaces 112c and 112d. Housing 110 can define a groove 114 in at least a portion of top surface 112c. Release latch 116 can be received at least partially within groove 114. Housing 110 may also define one or more vents 118 arranged along any suitable surface of housing 110. For example, a first vent 118 and a second vent 118 can be defined along bottom surface 112d of housing proximate to end 112. First and second vents 118 can be elongated in a direction perpendicular to a direction between ends 112a and 112b. Vent(s) 118 can provide an opening extending between a hollow internal region of housing 110 and the external environment. This enables the transfer of air from the external environment to the hollow internal region, and vice versa, using first and second fan units 150 and 160. One or more vents 118 can be defined in separate locations of housing 110 proximate to or adjacent where first and second fan units 150 and 160 are located.

Charging adaptor 100 can also include a first charging plug 120 having a plug housing 122 surrounding a plurality of conductors 124. First charging plug 120 may extend outward from end 112a at a position proximate to top surface 112c. Charging adaptor 100 can also include a second charging plug 130 having a plug housing 132 surrounding a plurality of conductors 134. Second charging plug 130 may extend outward from end 112a at a position proximate to bottom surface 112d and below first charging plug 120. In combination, first and second charging plugs 120 and 130 can be coupled to an electric vehicle inlet and configured to transfer electric current to the vehicle for charging. First and second charging plugs 120 and 130 may comprise a single, integrally formed charging plug in some examples of the present disclosure. First and second charging plugs 120 and 130 may be characterized as “first and second electrical contacts” or “one or more electrical contacts” in some examples.

Charging adaptor 100 may also include a charging socket 140 having a socket housing 142 surrounding a connector 144 and a plurality of conductors 146. Charging socket 140 may extend outward from end 112b at a position proximate to top surface 112c. Charging socket 140 can be coupled to an electric vehicle charging modality and configured to transfer electric current from the modality to first and second charging plugs 120 and 130. Current can then be transferred to the electric vehicle for charging. Charging socket 140 may be characterized as a “third electrical contact” or “one or more electrical contacts” when combined with first and second charging plugs 120 and 130. Charging adaptor 100 can also include a lock mechanism 148 positioned at end 112b. Lock mechanism 148 can be actuated to lock and unlock the coupling of charging socket 140 to the charging modality.

Charging adaptor 100 may also include first and second fan units 150 and 160 positioned within housing 110, for example within a hollow internal region of housing 110 defined between ends 112a and 112b. First fan unit 150 can include a duct 152 operably coupled to a fan 154. Similarly, second fan unit 160 can include a duct 162 operably coupled to a fan 164. First fan unit 150 can draw outside air into housing 110 through vent(s) 118 and can circulate the outside air along a heat sink 170. Specifically, air can be directed along a plurality of fins 174 extending outward from a mount plate 172 of heat sink 170 in a direction perpendicular to, or substantially perpendicular to, the flow of electric current from the charging station to the electric vehicle. Second fan unit 160 can exhaust the air out of housing 110 through the same or different vent(s) 118 to expel heat generated during electric vehicle charging.

The operation of first and second fan units 150 and 160 may generate a pressure differential that facilitates the transfer of air into and out of housing 110. In some examples, the pressure differential between fan units 150 and 160 can enable the circulation of air between ends 112a and 112b when the air is contained within housing 110. In some examples, first and second fan units 150 and 160 may be integrated into a single fan unit configured to perform the functions of both fan units 150 and 160. Regardless of whether a single fan unit or first and second fan units 150 and 160 are used, indirect cooling of charging plugs 120 and 130 and charging socket 140 (collectively “one or more electrical contacts” in some examples), along with other components positioned therebetween, can be achieved by dissipating heat from heat sink 170. For example, heat can be dissipated from various electrical components, including conductors 124, 134, and 146, via air directed along heat sink 170 and exhausted from housing 110.

Charging adaptor 100 may also include at least one heat sink 170 having a mount plate 172 and a plurality of fins 174 extending from mount plate 172. Heat sink(s) 170 may include any number, configuration, orientation, and arrangement of fins 174 along front and/or back sides of mount plate 172. Heat sink(s) 170 may be positioned proximate to first and second fan units 150 and 160 within housing 110, or positioned at any other location near electrical components that generate heat during charging. This can be, for example, conductors 124, 134, and 146 of first and second charging plugs 120 and 130 and charging socket 140, respectively.

Heat sink(s) 170 can receive and store heat generated during electric vehicle charging. In some examples, heat can be transferred to heat sink 170 from a heat-conducting dielectric 184 positioned proximate to or adjacent heat sink 170 (e.g., dielectric 184 can be in direct contact with one or more heat sinks 170 or spaced in proximity). In some examples, dielectric 184 can at least partially surround conducting straps 182 when positioned within housing 110. In some examples, dielectric 184 may comprise a thermoset material such as an epoxy resin. Dielectric 184 can be used to isolate the positive and negative high voltage conductors within housing 110, namely conductors 124 and 134, to prevent electrical arcing during use. Dielectric 184 can also act as a sealant for conductors 124 and 134 to prevent water ingress in the region proximate charging plugs 120 and 130. In general, dielectric 184 can enable heat transfer from charging plugs 120 and 130 to dielectric 184 and then to heat sink 170 from dielectric 184.

Accordingly, heat generated during electric vehicle charging can be transferred from one or more electrical contacts, such as charging plugs 120 and 130, to dielectric 184 and then to heat sink 170. First fan unit 150 can draw outside air into housing 110 through one or more vents 118 and can direct the outside air along and around heat sink 170. Air can subsequently be exhausted from housing 110 through one or more vents 118 to dissipate the generated heat. This process can be repeated continuously or intermittently during electric vehicle charging. As such, forced-air as a non-liquid cooling medium can dissipate heat from charging adaptor 100 to eliminate or significantly reduce the risk of overheating during charging. Cooling the charging adaptor 100 directly provides indirect cooling on both sides of the charging process, namely the charging station charging modality and the electric vehicle inlet.

Charging adaptor 100 may also include various mechanical and/or electrical components 190 located within housing 110. Components 190 may include at least one circuit board 192 for controlling various electrical components, including those of first and second charging plugs 120 and 130, charging socket 140, and first and second fan units 150 and 160, for example. Circuit board(s) 192 may be positioned in any suitable location between ends 112a and 112b within housing 110. Other electrical components such as sensors and processors may be included with charging adaptor 100 or otherwise coupled to adaptor 100 (e.g., wirelessly or communicatively coupled). The sensors and processors may be used to operate first and second fan units 150 and 160 during electric vehicle charging.

Additional background information about electric vehicles and electric vehicle charging is provided in commonly owned U.S. Patent Publication No. 2024/0262162A1 to Micheau-Cunningham, filed Jan. 1, 2024 as application Ser. No. 18/423,138 and titled “ACTIVE AND PASSIVE HEAT EXCHANGER FOR COOLING ELECTRIC VEHICLE CHARGING HANDLES,” the disclosure of which is hereby incorporated by reference in its entirety.

Various examples of systems, devices, and methods have been described herein. These examples are given only by way of example and are not intended to limit the scope of the claimed inventions. It should be appreciated, moreover, that the various features of the examples that have been described may be combined in various ways to produce numerous additional examples. Moreover, while various materials, dimensions, shapes, configurations, geometries and locations, etc. have been described for use with disclosed examples, others besides those disclosed may be utilized without exceeding the scope of the claimed inventions.

Persons of ordinary skill in the relevant arts will recognize that the subject matter hereof may comprise fewer features than illustrated in any individual example described above. The examples described herein are not meant to be an exhaustive presentation of the ways in which the various features of the subject matter hereof may be combined. Accordingly, the examples are not mutually exclusive combinations of features; rather, the various examples can comprise a combination of different individual features selected from different individual examples, as understood by persons of ordinary skill in the art. Moreover, elements described with respect to one example can be implemented in other examples even when not described in such examples unless otherwise noted.

Although a dependent claim may refer in the claims to a specific combination with one or more other claims, other examples can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112 (f) are not to be invoked unless the specific terms “means for” or “step for” are recited in a claim.

1. A charging adaptor for an electric vehicle comprising:
a housing defining one or more vents;
at least one fan unit positioned within the housing proximate to the one or more vents; and
a heat sink positioned within the housing proximate to the at least one fan unit, the heat sink configured to absorb heat generated during electric vehicle charging,
wherein the at least one fan unit is configured to draw outside air into the housing through the one or more vents and is configured to direct the outside air along the heat sink.

2. The charging adaptor of claim 1, wherein the at least one fan unit comprises a first fan unit and a second fan unit.

3. The charging adaptor of claim 1, wherein the at least one fan unit comprises a fan duct and a forced-air fan.

4. The charging adaptor of claim 1, wherein the at least one fan unit is further configured to exhaust the outside air out of the housing through the one or more vents after the outside air is directed along the heat sink.

5. The charging adaptor of claim 1, wherein the heat sink comprises a plurality of fins extending outward from a mount plate.

6. The charging adaptor of claim 1, wherein the at least one fan unit is powered by an electrical source positioned within the housing.

7. The charging adaptor of claim 1, wherein the at least one fan unit is powered by a battery.

8. The charging adaptor of claim 1, further comprising one or more electrical contacts, wherein heat generated by the one or more electrical contacts during electric vehicle charging is transferred to a dielectric positioned within the housing, and wherein heat is transferred from the dielectric to the heat sink.

9. The charging adaptor of claim 8, wherein the one or more electrical contacts comprise a charging plug having one or more conductors for transmitting electrical current.

10. A charging adaptor for an electric vehicle comprising:
a housing defining one or more vents;
one or more electrical contacts coupled to the housing;
a dielectric positioned proximate to the one or more electrical contacts;
a first fan unit positioned within the housing proximate to the one or more vents;
a second fan unit positioned within the housing proximate to the one or more vents; and
a heat sink positioned within the housing proximate to each of the dielectric, the first fan unit, and the second fan unit, wherein heat generated by the one or more electrical contacts during electric vehicle charging is transferred first to the dielectric and then to the heat sink,
wherein the first fan unit draws outside air into the housing through the one or more vents and directs the outside air along the heat sink, and wherein the second fan unit exhausts the outside air out of the housing through the one or more vents after the outside air is directed along the heat sink.

11. The charging adaptor of claim 10, wherein the one or more vents comprise a first vent and a second vent defined in a bottom surface of the housing, and wherein the first fan unit is positioned proximate to the first vent and the second fan unit is positioned proximate to the second vent.

12. The charging adaptor of claim 10, wherein the heat sink comprises a plurality of fins extending outward from a mount plate toward the first fan unit and the second fan unit.

13. The charging adaptor of claim 10, wherein the first fan unit and the second fan unit are powered by at least one of an electrical source positioned within the housing and a battery.

14. The charging adaptor of claim 10, wherein the first fan unit and the second fan unit each comprise a fan duct and a forced-air fan.

15. The charging adaptor of claim 10, wherein the one or more electrical contacts comprise a charging plug having a plurality of conductors, and wherein the plurality of conductors generate heat during electric vehicle charging that is transferred to the dielectric.

16. A cooling system for an electric vehicle charging adaptor comprising:
a first fan unit configured to draw outside air into the charging adaptor;
a second fan unit configured to exhaust air out of the charging adaptor; and
a heat sink having a plurality of fins extending from a mount plate, the heat sink configured to receive heat generated during electric vehicle charging,
wherein the first fan unit draws outside air into the charging adaptor and directs the outside air along the heat sink, and wherein the second fan unit exhausts the outside air out of the charging adaptor after the outside air is directed along the heat sink.

17. The cooling system of claim 16, wherein the first fan unit and the second fan unit are horizontally aligned with respect to the mount plate, such that air is directed toward the plurality of fins by the first fan unit and directed away from the plurality of fins by the second fan unit.

18. The cooling system of claim 16, wherein the first fan unit circulates forced-air as a non-liquid cooling medium along the heat sink.

19. The cooling system of claim 16, wherein the first fan unit and the second fan unit are operable upon detecting electric vehicle charging.

20. The cooling system of claim 16, further comprising a dielectric positioned proximate to the heat sink, wherein heat generated during electric vehicle charging is transferred from the dielectric to the heat sink.
